(19) United States
(12) Patent Application Publication
(10) Pub. No.: US 2025/0210503 A1
(43) Pub. Date: Jun. 26, 2025

(54) SEMICONDUCTOR DEVICE

(71) Applicants: KABUSHIKI KAISHA TOSHIBA, Tokyo (JP); Toshiba Electronic Devices & Storage Corporation, Tokyo (JP)

(72) Inventor: Fumiyoshi Kawashiro, Tokyo (JP)

(73) Assignees: KABUSHIKI KAISHA TOSHIBA, Tokyo (JP); Toshiba Electronic Devices & Storage Corporation, Tokyo (JP)

(21) Appl. No.: 19/077,143

(22) Filed: Mar. 12, 2025

Related U.S. Application Data
(63) Continuation of application No. PCT/JP2024/006394, filed on Feb. 21, 2024.

(30) Foreign Application Priority Data
Jul. 31, 2023 (JP) 2023-124505

(51) Int. Cl. H01L 23/498; H01L 21/60; H01L 23/00; H01L 23/053; H01L 23/08; H01L 23/15; H01L 23/538; H01L 25/07; H10D 80/20

(52) U.S. Cl. CPC H01L 23/49838; H01L 23/053; H01L 23/5386; H01L 21/60; H01L 2021/60195; H01L 23/08; H01L 23/15; H01L 23/49894; H01L 24/48; H01L 25/072; H01L 2224/48091; H01L 2224/48225; H01L 2924/10272; H01L 2924/13055; H01L 2924/13091; H10D 80/251

(57) ABSTRACT

According to one embodiment, a semiconductor device includes a base substrate; a case provided on the base substrate; a first stack provided inside the case on the base substrate; a second stack provided apart from the first stack on the base substrate; and a first conductor having a flat plate shape and including a first portion in contact with the first stack and a second portion in contact with the second stack. The first stack includes a first insulator, a second conductor provided on the first insulator and in contact with the first portion, and a first semiconductor element electrically connected to the second conductor. The second stack includes a second insulator and a third conductor provided on the second insulator and in contact with the second portion, and does not include a semiconductor element.

### CROSS-REFERENCE TO RELATED APPLICATIONS

This application is a Continuation Application of PCT Application No. PCT/JP2024/006394, filed Feb. 21, 2024; and based upon and claims the benefit of priority from Japanese Patent Application No. 2023-124505, filed Jul. 31, 2023, the entire contents of which are incorporated herein by reference.

### FIELD

Embodiments described herein relate generally to a semiconductor device.

### BACKGROUND

A power module has been known as a semiconductor device that realizes high output. The power module is configured as one package in which a plurality of power semiconductors is integrated.

### BRIEF DESCRIPTION OF THE DRAWINGS

FIG. 1 is a perspective view illustrating an external structure of a semiconductor device according to a first embodiment.

FIG. 2 is a circuit diagram illustrating an example of a circuit configuration of the semiconductor device according to the first embodiment.

FIG. 3 is a cross-sectional view illustrating a first example of a cross-sectional structure of the semiconductor device according to the first embodiment.

FIG. 4 is a cross-sectional view illustrating a second example of the cross-sectional structure of the semiconductor device according to the first embodiment.

FIG. 5 is a cross-sectional view illustrating a first example of a cross-sectional structure of a semiconductor device according to a second embodiment.

FIG. 6 is a cross-sectional view illustrating a second example of the cross-sectional structure of the semiconductor device according to the second embodiment.

FIG. 7 is a cross-sectional view illustrating a first example of a cross-sectional structure of a semiconductor device according to a third embodiment.

FIG. 8 is a cross-sectional view illustrating a second example of the cross-sectional structure of the semiconductor device according to the third embodiment.

FIG. 9 is a cross-sectional view illustrating a first example of a cross-sectional structure of a semiconductor device according to a fourth embodiment.

FIG. 10 is a cross-sectional view illustrating a second example of the cross-sectional structure of the semiconductor device according to the fourth embodiment.

FIG. 11 is a cross-sectional view illustrating a first example of a cross-sectional structure of a semiconductor device according to a fifth embodiment.

FIG. 12 is a cross-sectional view illustrating a second example of the cross-sectional structure of the semiconductor device according to the fifth embodiment.

FIG. 13 is a cross-sectional view illustrating an example of a cross-sectional structure of a semiconductor device according to a first modification.

FIG. 14 is a cross-sectional view illustrating an example of a cross-sectional structure of a semiconductor device according to a second modification.

FIG. 15 is a cross-sectional view illustrating an example of a cross-sectional structure of a semiconductor device according to a third modification.

### DETAILED DESCRIPTION

In general, according to one embodiment, a semiconductor device includes a base substrate; a case provided on an upper surface of the base substrate; a first stack provided inside the case on the upper surface of the base substrate; a second stack provided apart from the first stack on the upper surface of the base substrate; and a first conductor having a flat plate shape and including a first portion in contact with the first stack and a second portion in contact with the second stack. The first stack includes a first insulator, a second conductor provided on an upper surface of the first insulator and in contact with the first portion of the first conductor, and a first semiconductor element electrically connected to the second conductor. The second stack includes a second insulator and a third conductor provided on an upper surface of the second insulator and in contact with the second portion of the first conductor, and does not include a semiconductor element.

Hereinafter, embodiments will be described with reference to the drawings. Dimensions and ratios of the drawings are not necessarily the same as actual ones.

Note that, in the following description, components having substantially the same functions and configurations are denoted by the same reference numerals. In a case where elements having similar configurations are particularly distinguished from each other, different characters or numbers may be added to the end of the same reference numeral.

### 1. First Embodiment

A semiconductor device according to a first embodiment will be described.

The semiconductor device according to the first embodiment is a power module. The semiconductor device according to the first embodiment is applied to, for example, a power conversion device for a railway vehicle or a power unit such as industrial equipment.

A configuration of the semiconductor device according to the first embodiment will be described.

First, an external structure of the semiconductor device according to the first embodiment will be described.

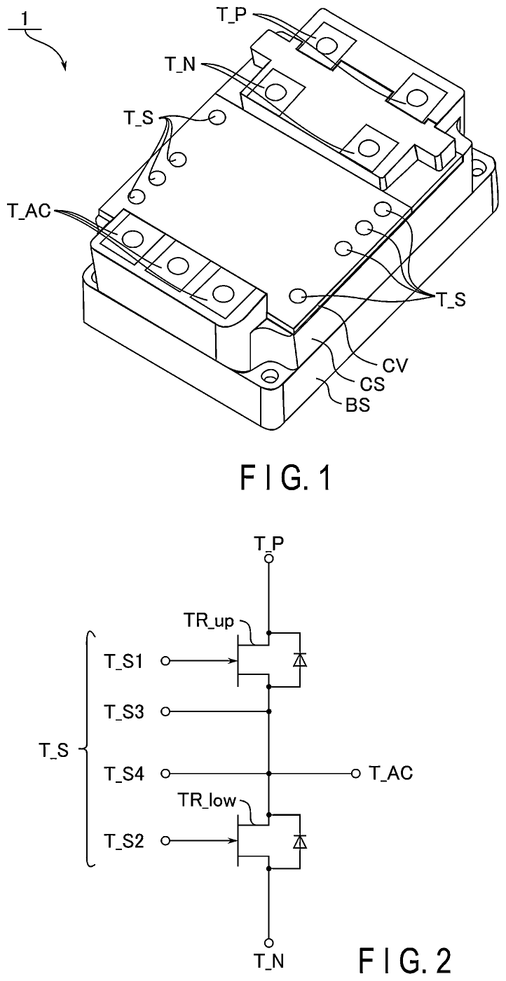

FIG. 1 is a perspective view illustrating an example of an external structure of the semiconductor device according to the first embodiment. The semiconductor device 1 includes a base substrate BS, a case CS, and a lid CV as external structures. The base substrate BS, the case CS, and the lid CV form a container of the semiconductor device 1. A circuit configuration (not illustrated) including a semiconductor element is accommodated in the container of the semiconductor device 1.

The base substrate BS is a support member corresponding to a lower portion of the container of the semiconductor device 1. The base substrate BS has a flat plate shape. The base substrate BS is fixed to a device (not illustrated) outside the semiconductor device 1 through, for example, screw holes formed at four corners.

The case CS is provided on an upper surface of the base substrate BS. The case CS is an insulator having a rectangular tube shape. The case CS corresponds to a side portion of the container of the semiconductor device 1. The case CS is fixed to the base substrate BS.

The lid CV is provided on an upper surface of the case CS. The lid CV is an insulator having a flat plate shape. The lid CV corresponds to an upper portion of the container of the semiconductor device 1. The lid CV is fixed to the case CS.

The base substrate BS, the case CS, and the lid CV are assembled as described above, so that a space for arranging the circuit configuration is formed inside the container.

The semiconductor device 1 further includes a plurality of terminals T(T_P, T_N, T_AC, and T_S).

Each of the terminals T_P, T_N, T_AC, and T_S is an end of a bus bar (not illustrated) that electrically connects an external device of the semiconductor device 1 and an internal circuit configuration. In the example of FIG. 1, two terminals T_P, two terminals T_N, three terminals T_AC, and eight terminals T_S are illustrated. Note that the number of each of the terminals T_P, T_N, T_AC, and T_S is not limited to the example of FIG. 1, and may be designed as an any number.

The two terminals T_P are input terminals. The two terminals T_P have a positive (P) polarity. The two terminals T_P are electrically connected to each other. The two terminals T_P are arranged on one of two short sides facing each other of the semiconductor device 1.

The two terminals T_N are input terminals. The two terminals T_N have a negative (N) polarity. The two terminals T_N are electrically connected to each other. The two terminals T_N are arranged so as to be aligned with the two terminals T_P on the one of the two short sides facing each other of the semiconductor device 1.

The three terminals T_AC are output terminals. The three terminals T_AC are also called alternating current (AC) terminals. The three terminals T_AC are electrically connected to each other. The three terminals T_AC are arranged on the other of the two short sides facing each other of the semiconductor device 1.

The eight terminals T_S are control terminals and monitor terminals. The control terminal is, for example, a terminal for controlling whether or not to drive a semiconductor element included in the circuit configuration of the semiconductor device 1. The monitor terminal is, for example, a terminal for monitoring an electrical characteristic of a circuit configuration of the semiconductor device 1. Four of the eight terminals T_S are arranged on each of two opposing long sides of the semiconductor device 1.

Next, a circuit configuration of the semiconductor device according to the first embodiment will be described.

FIG. 2 is a circuit diagram illustrating an example of a circuit configuration of the semiconductor device according to the first embodiment. As illustrated in FIG. 2, the plurality of terminals T_S include terminals T_S1, T_S2, T_S3, and T_S4. Furthermore, in the example of FIG. 2, a case where the semiconductor device 1 includes transistors TR_up and TR_low as electrical elements included in an internal circuit configuration is illustrated.

The transistors TR_up and TR_low are, for example, insulated gate bipolar transistors (IGBTs) or field effect transistors (MOSFET: Metal-Oxide-Silicon Field-Effect Transistor) using silicon carbide (SiC). The transistors TR_up and TR_low are connected in series. In the example of FIG. 2, one transistor TR_up and one transistor TR_low are illustrated, but this embodiment is not limited thereto. For example, each of the transistors TR_up and TR_low may include a plurality of transistors connected in parallel to each other.

Specifically, the transistor TR_up has a drain end connected to the terminal T_P, a source end connected to a drain end of the transistor TR_low, and a gate end connected to the terminal T_S1. The transistor TR_low has the drain end connected to the source end of the transistor TR_up, a source end connected to the terminal T_N, and a gate end connected to the terminal T_S2. The source end of the transistor TR_up and the drain end of the transistor TR_low are commonly connected to the terminal T_AC, the terminal T_S3, and the terminal T_S4.

The terminals T_S1 and T_S2 correspond to two different control terminals of the terminal T_S, respectively. The terminals T_S3 and T_S4 respectively correspond to two monitor terminals different from each other among terminals T_S. Note that the terminal T_S3 is located closer to the transistor TR_up than the terminal T_AC. The terminal T_S4 is located closer to the transistor TR_low side than the terminal T_3.

With the above configuration, the semiconductor element inside the semiconductor device 1 can be controlled by a voltage supplied from the outside of the semiconductor device 1.

Next, a cross-sectional structure of the semiconductor device according to the first embodiment will be described.

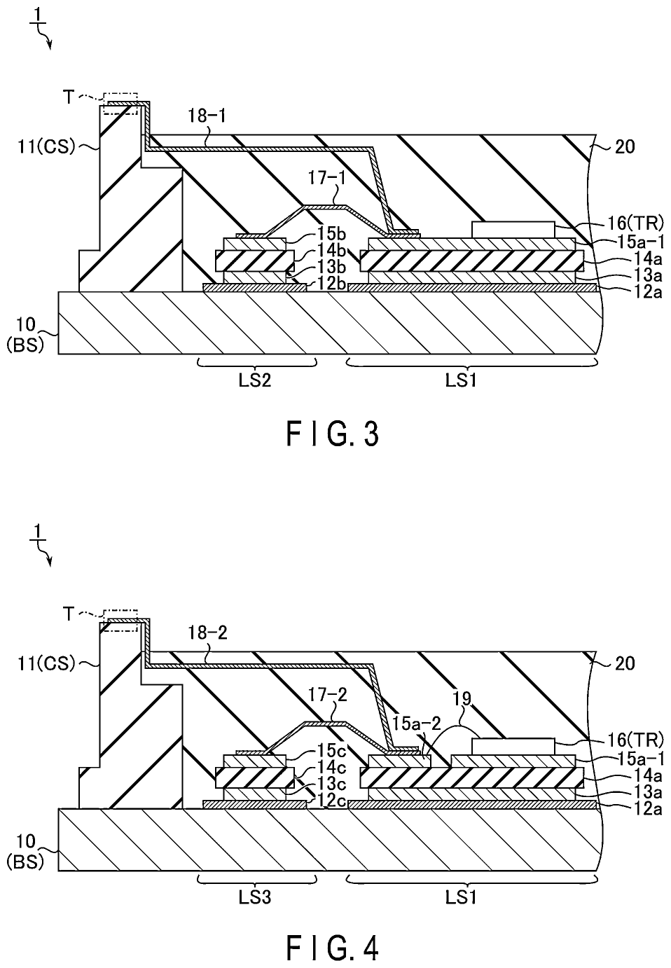

FIG. 3 is a cross-sectional view illustrating a first example of a cross-sectional structure of the semiconductor device according to the first embodiment. FIG. 4 is a cross-sectional view illustrating a second example of the cross-sectional structure of the semiconductor device according to the first embodiment. The first example and the second example are cross-sectional views of the semiconductor device 1 along different cross-sections. Specifically, in the first example, an example of a cross-sectional structure of the semiconductor device 1 in a portion where the bus bar functioning as the terminal T and the transistor TR are provided on the same conductor is shown. In the second example, an example of a cross-sectional structure of the semiconductor device 1 in a portion where the bus bar functioning as the terminal T and the transistor TR are provided on different conductors is shown.

The semiconductor device 1 includes conductors 10, 12, 13, 15, 17, 18, and 19, insulators 11, 14, and 20, and a semiconductor element 16. The conductor 12 includes conductors 12a, 12b, and 12c. The conductor 13 includes conductors 13a, 13b, and 13c. The insulator 14 includes insulators 14a, 14b, and 14c. The conductor 15a includes conductors 15a-1, 15a-2, 15b, and 15c. The conductor 17 includes conductors 17-1 and 17-2. The conductor 18 includes conductors 18-1 and 18-2.

The conductor 10 corresponds to the base substrate BS. The conductor 10 contains, for example, copper (Cu) or ceramics.

The insulator 11 corresponding to the case CS is provided on an upper surface of the conductor 10. The insulator 11 contains, for example, poly-phenylene sulfide (PPC).

Three stacks LS1, LS2, and LS3 are provided apart from each other in a region (inner side) surrounded by the insulator 11 on the upper surface of the conductor 10.

As illustrated in FIGS. 3 and 4, the stack LS1 includes the conductor 12a, the conductor 13a, the insulator 14a, the conductors 15a-1 and 15a-2, and the semiconductor element 16. The conductor 12a is provided on the upper surface of the conductor 10. The conductor 12a includes, for example, solder. The conductor 13a is provided on an upper surface of the conductor 12a. The conductor 13a contains, for example, copper (Cu). The insulator 14a is provided on an upper surface of the conductor 13a. The insulator 14a is, for example, an insulating substrate including insulating ceramics such as aluminum nitride (AlN) and silicon nitride (SiN). The conductors 15a-1 and 15a-2 are provided apart from each other on an upper surface of the insulator 14a. The conductors 15a-1 and 15a-2 contain, for example, copper (Cu). The semiconductor element 16 is provided on an upper surface of the conductor 15a-1. That is, the insulator 14a is an insulating substrate on which the semiconductor element 16 is mounted. The semiconductor element 16 is a chip including the transistor TR (TR_up or TR_low). An upper surface of the semiconductor element 16 and an upper surface of the conductor 15a-2 are electrically connected by the conductor 19. The conductor 19 is, for example, a bonding wire.

As illustrated in FIG. 3, the stack LS2 includes the conductor 12b, the conductor 13b, the insulator 14b, and the conductor 15b. The conductor 12b is provided on the upper surface of the conductor 10. The conductor 12b includes, for example, solder. The conductor 13b is provided on an upper surface of the conductor 12b. The conductor 13b contains, for example, copper (Cu). The insulator 14b is provided on an upper surface of the conductor 13b. The insulator 14b includes, for example, insulating ceramics such as aluminum nitride (AlN) and silicon nitride (SiN). The conductor 15b is provided on an upper surface of the insulator 14b. The conductor 15b contains, for example, copper (Cu). Note that the semiconductor element 16 is not provided above the insulator 14b. That is, all the semiconductor elements 16 included in the semiconductor device 1 are not included in the stack LS2.

As illustrated in FIG. 4, the stack LS3 includes the conductor 12c, the conductor 13c, the insulator 14c, and the conductor 15c. The conductor 12c is provided on the upper surface of the conductor 10. The conductor 12c includes, for example, solder. The conductor 13c is provided on an upper surface of the conductor 12c. The conductor 13c contains, for example, copper (Cu). The insulator 14c is provided on an upper surface of the conductor 13c. The insulator 14c is, for example, an insulating substrate including insulating ceramics such as aluminum nitride (AlN) and silicon nitride (SiN). The conductor 15c is provided on an upper surface of the insulator 14c. The conductor 15c contains, for example, copper (Cu). Note that the semiconductor element 16 is not provided above the insulator 14c. That is, all the semiconductor elements 16 included in the semiconductor device 1 are not included in the stack LS3.

The stacks LS2 and LS3 are disposed between the stack LS1 and the insulator 11. That is, the stacks LS2 and LS3 are disposed closer to the insulator 11 (outside) than the stack LS1 as viewed in the vertical direction.

The conductors 17-1, 17-2, 18-1, and 18-2 are, for example, flat plate-shaped conductive materials and contain copper (Cu). The conductors 17-1, 17-2, 18-1, and 18-2 are formed by bending a flat plate having a substantially uniform thickness, for example. The thicknesses of the conductors 17-1, 17-2, 18-1, and 18-2 are designed in a range of, for example, 0.4 mm or more and 4.0 mm or less.

The conductor 17-1 has a first end bonded on the upper surface of the conductor 15a-1 and a second end bonded on an upper surface of the conductor 15b. The conductor 18-1 has a first end bonded on an upper surface of the first end of the conductor 17-1 and a second end disposed on an upper surface of the insulator 11 and functioning as the terminal T. The first end of the conductor 17-1 is electrically connected to the semiconductor element 16 through the conductor 15a-1, and is electrically connected to the terminal T through the conductor 18-1. The second end of the conductor 17-1 is connected to the insulator 14b through the conductor 15b. As a result, the conductor 17-1 functions as a path to transfer heat from the semiconductor element 16 to the conductor 10 through the insulator 14b, the heat would otherwise be transferred to the insulator 14a or the terminal T if the conductor 17-1 is not provided.

The conductor 17-2 has a first end bonded on the upper surface of the conductor 15a-2 and a second end bonded on an upper surface of the conductor 15c. The conductor 18-2 has a first end bonded on the upper surface of the first end of the conductor 17-2 and a second end disposed on the upper surface of the insulator 11 and functioning as the terminal T. The first end of the conductor 17-2 is electrically connected to the semiconductor element 16 through the conductors 15a-2 and 19, and is electrically connected to the terminal T through the conductor 18-2. The second end of the conductor 17-2 is connected to the insulator 14c through the conductor 15c. As a result, the conductor 17-2 functions as a path to transfer heat from the semiconductor element 16 to the conductor 10 through the insulator 14c, the heat would otherwise be transferred to the insulator 14a or the terminal T if the conductor 17-2 is not provided.

The first end of the conductor 17-1 and the conductor 15a-1, the second end of the conductor 17-1 and the conductor 15b, the first end of the conductor 17-2 and the conductor 15a-2, and the second end of the conductor 17-2 and the conductor 15c are bonded by ultrasonic bonding, for example. Similarly, the first end of the conductor 18-1 and the first end of the conductor 17-1, and the first end of the conductor 18-2 and the first end of the conductor 17-2 are bonded by ultrasonic bonding, for example. In this case, an indentation having fine protrusions and recesses as if a knurling shape is transferred is formed on the upper surface of each of the first end and the second end of the conductor 17-1, the first end and the second end of the conductor 17-2, the first end of the conductor 18-1, and the first end of the conductor 18-2.

Each of the second end of the conductor 18-1 and the second end of the conductor 18-2 is bonded to an external device through a screw hole (not illustrated), for example. The type of the terminal T corresponding to the second end of the conductor 18-1 and the second end of the conductor 18-2 may be any of the terminals T_P, T_N, T_AC, and T_S. In a case where the semiconductor element 16 is the transistor TR_up, the second end of the conductor 18-1 and the second end of the conductor 18-2 may be the terminal T_P and the terminals T_AC, T_S1, or T_S3, respectively. In a case where the semiconductor element 16 is the transistor TR_low, the second end of the conductor 18-1 and the second end of the conductor 18-2 may be the terminal T_AC or T_S4 and the terminal T_N or T_S2, respectively.

A length of a portion between the first end and the second end of the conductor 17-1 in the depth direction of the paper surface is preferably designed to be longer than a length of a portion between the first end and the second end of the conductor 18-1 in the depth direction of the paper surface by, for example, 0.5 mm or more. In this case, in a case where the inside of the semiconductor device 1 is viewed from above to below, a part of the conductor 17-1 can be visually recognized without being hidden by the conductor 18-1.

Similarly, a length of a portion between the first end and the second end of the conductor 17-2 in the depth direction of the paper surface is preferably designed to be longer than a length of a portion between the first end and the second end of the conductor 18-2 in the depth direction of the paper surface by, for example, 0.5 mm or more. In this case, in a case where the inside of the semiconductor device 1 is viewed from above to below, a part of the conductor 17-2 can be visually recognized without being hidden by the conductor 18-2.

An internal structure of the semiconductor device 1 configured as described above is sealed by the insulator 20 except for the portion functioning as the terminal T in the conductors 18-1 and 18-2. The insulator 20 has a function of physically and electrically protecting the internal structure of the semiconductor device 1 from the outside of the semiconductor device 1.

According to the first embodiment, a temperature rise of the semiconductor device 1 can be suppressed. This effect will be described below.

The insulators 14a, 14b, and 14c are provided apart from each other on the upper surface of the conductor 10. The conductors 15a-1 and 15a-2 are provided on the upper surface of the insulator 14a. The conductors 15b and 15c are provided on the upper surfaces of the insulators 14b and 14c, respectively. The conductor 17-1 has a first end in contact with the conductor 15a-1 and a second end in contact with the conductor 15b. The conductor 17-2 has a first end in contact with the conductor 15a-2 and a second end in contact with the conductor 15c. The semiconductor element 16 is electrically connected to the conductors 17-1 and 17-2. As a result, the conductors 17-1 and 17-2 can form heat radiation paths for releasing heat generated in the semiconductor element 16 to the conductor 10 through the stacks LS2 and LS3, respectively. Therefore, the temperature rise of the stack LS1 including the semiconductor element 16 can be suppressed.

The conductor 18-1 has a first end in contact with the first end of the conductor 17-1 and a second end positioned on the upper surface of the insulator 11 and functioning as the terminal T. The conductor 18-2 has a first end in contact with the first end of the conductor 17-2 and a second end positioned on the upper surface of the insulator 11 and functioning as the terminal T. As a result, the conductors 17-1 and 17-2 can form a heat radiation path for releasing the heat flowing into the terminal T to the conductor 10 through the stacks LS2 and LS3, respectively. Therefore, the temperature rise of the terminal T can be suppressed.

To supplement, the outer shape of the semiconductor device 1 is standardized for the purpose of improving user convenience. As a result, the semiconductor device 1 is required to increase a current capacity to a degree within a range of the standard. As the current capacity increases, the heat flowing into the stack LS1 including the semiconductor element 16 and the terminal T increases.

According to the first embodiment, the stack LS1 and the terminal T are connected to the stacks LS2 and LS3, respectively, through the conductors 17-1 and 17-2. The stacks LS2 and LS3 do not include the semiconductor element 16. As a result, the stacks LS2 and LS3 can function as a heat dissipation mechanism that suppresses a temperature rise of the stack LS1 and the terminal T without serving as a heat source.

In addition, the conductors 17-1, 17-2, 18-1, and 18-2 contain copper (Cu) as an equivalent material. As a result, the mismatch of the thermal expansion coefficient of the bonded portion due to the temperature rise is suppressed. In addition, the conductors 17-1, 17-2, 18-1, and 18-2 are ultrasonically bonded. As a result, for example, it is possible to suppress deterioration in strength of the bonded portion due to a temperature rise as compared with the case of connection through solder.

### 2. Second Embodiment

Next, a semiconductor device according to a second embodiment will be described.

The second embodiment is different from the first embodiment in that a bus bar forming a heat radiation path is formed integrally with a bus bar functioning as a terminal T. Hereinafter, a configuration different from that of the first embodiment will be mainly described. Description of configurations similar to those of the first embodiment will be omitted as appropriate.

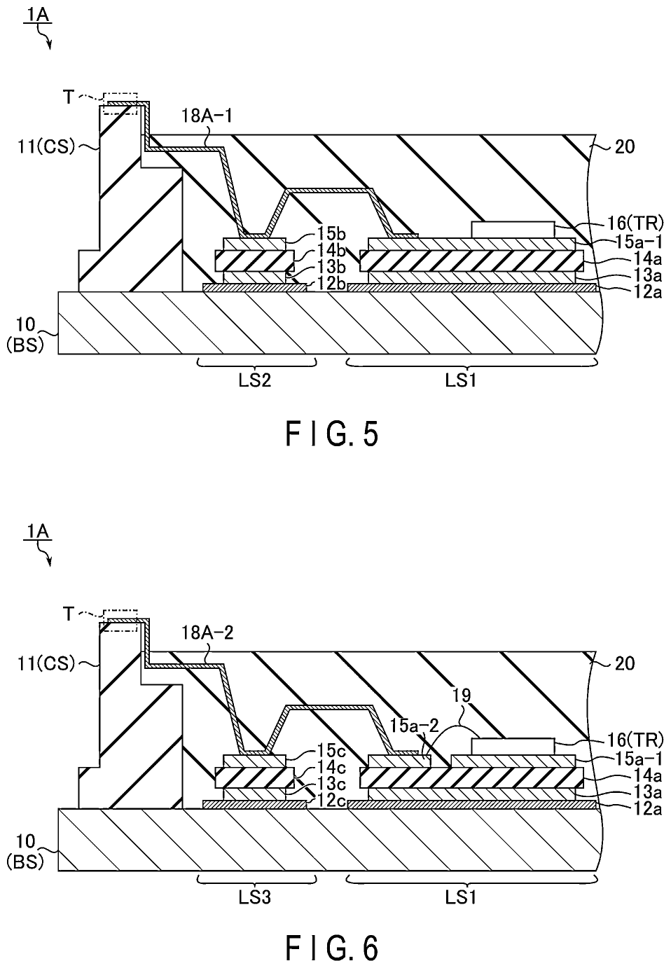

FIG. 5 is a cross-sectional view illustrating a first example of a cross-sectional structure of a semiconductor device according to a second embodiment. FIG. 6 is a cross-sectional view illustrating a second example of the cross-sectional structure of the semiconductor device according to the second embodiment. FIGS. 5 and 6 correspond to FIGS. 3 and 4 in the first embodiment, respectively.

The semiconductor device 1A according to the second embodiment includes conductors 18A-1 and 18A-2 instead of the conductors 17-1 and 18-1 and the conductors 17-2 and 18-2, respectively. The configuration of the semiconductor device 1A excluding the conductors 18A-1 and 18A-2 is similar to the corresponding configuration of the semiconductor device 1 according to the first embodiment.

The conductors 18A-1 and 18A-2 are, for example, flat plate-shaped conductive materials and contain copper (Cu). The conductors 18A-1 and 18A-2 are formed, for example, by bending a flat plate having a substantially uniform thickness. The thicknesses of the conductors 18A-1 and 18A-2 are designed in a range of, for example, 0.4 mm or more and 4.0 mm or less.

The conductor 18A-1 has a first end bonded on an upper surface of a conductor 15a-1, a second end positioned on an upper surface of an insulator 11 and functioning as a terminal T, and a central portion positioned between the first end and the second end and bonded on an upper surface of the conductor 15b. As a result, the conductor 18A-1 functions as a path to transfer heat from the semiconductor element 16 to the conductor 10 through an insulator 14b, the heat would otherwise be transferred to the insulator 14a or the terminal T if the conductor 18A-1 is not provided.

The conductor 18A-2 has a first end bonded on an upper surface of the conductor 15a-2, a second end positioned on an upper surface of the insulator 11 and functioning as the terminal T, and a central portion positioned between the first end and the second end and bonded on an upper surface of a conductor 15c. As a result, the conductor 18A-2 functions as a path to transfer heat from the semiconductor element 16 to the conductor 10 through an insulator 14c, the heat would otherwise be transferred to the insulator 14a or the terminal T if the conductor 18A-2 is not provided.

The first end of the conductor 18 A-1 and the conductor 15a-1, and the central portion of the conductor 18A-1 and the conductor 15b are bonded by ultrasonic bonding, for example. Similarly, the first end of the conductor 18A-2 and the conductor 15a-2, and the central portion of the conductor 18A-2 and the conductor 15c are bonded by ultrasonic bonding, for example. In this case, an indentation having fine protrusions and recesses as if a knurled shape is transferred is formed on each of the upper surfaces of the first end and the central portion of the conductor 18A-1 and the first end and the central portion of the conductor 18A-2.

An internal structure of the semiconductor device 1 configured as described above is sealed by an insulator 20 except for the portion functioning as the terminal T in the conductors 18A-1 and 18A-2.

According to the second embodiment, the conductor 18A-1 has a first end in contact with the conductor 15a-1, a second end positioned on the upper surface of the insulator 11 and functioning as the terminal T, and a central portion positioned between the first end and the second end and in contact with the conductor 15b. The conductor 18A-2 has a first end in contact with the conductor 15a-2, a second end positioned on the upper surface of the insulator 11 and functioning as the terminal T, and a central portion positioned between the first end and the second end and in contact with the conductor 15c. As a result, the conductors 18A-1 and 18A-2 can function as a heat radiation path for releasing the heat flowing into the terminal T and a stack LS1 to the conductor 10 through stacks LS2 and LS3, and can also function as a current path between the terminal T and the semiconductor element 16.

### 3. Third Embodiment

Next, a semiconductor device according to a third embodiment will be described.

The third embodiment is different from the first embodiment and the second embodiment in that a heat radiation path is formed inside a case CS. Hereinafter, configurations different from those of the first embodiment and the second embodiment will be mainly described. Description of configurations similar to those of the first embodiment and the second embodiment will be omitted as appropriate.

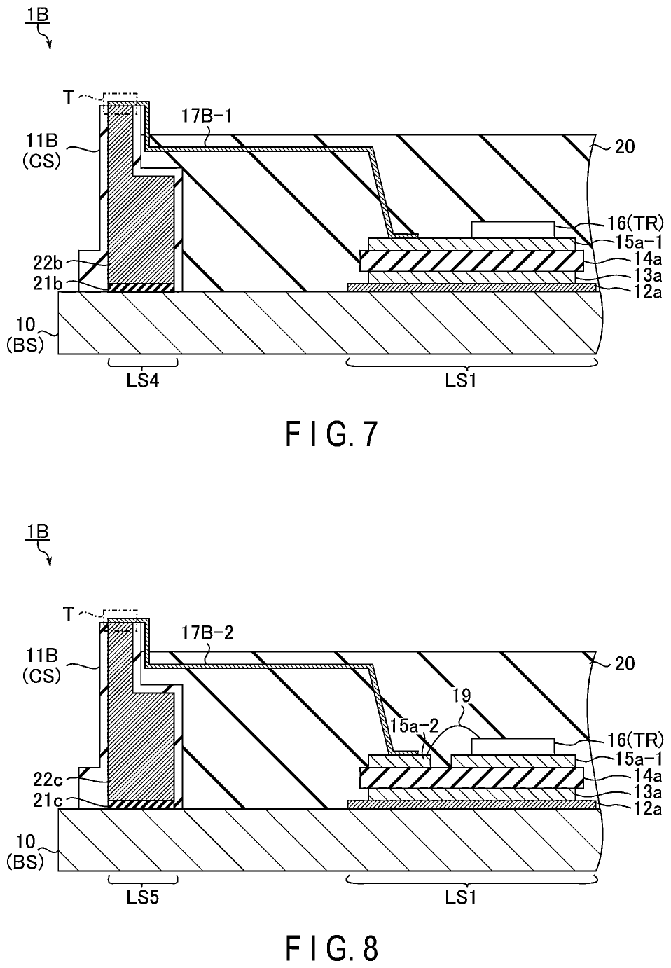

FIG. 7 is a cross-sectional view illustrating a first example of a cross-sectional structure of the semiconductor device according to the third embodiment; FIG. 8 is a cross-sectional view illustrating a second example of the cross-sectional structure of the semiconductor device according to the third embodiment. FIGS. 7 and 8 correspond to FIGS. 3 and 4 in the first embodiment, respectively.

A semiconductor device 1B according to a third embodiment includes conductors 17B-1 and 17B-2 instead of the conductors 17-1 and 18-1 and the conductors 17-2 and 18-2, respectively. In addition, the semiconductor device 1B according to the third embodiment includes an insulator 11B, a stack LS4, and a stack LS5 instead of the insulator 11, the stack LS2, and the stack LS3, respectively. The configuration of the semiconductor device 1B excluding the conductors 17B-1 and 17B-2, the insulator 11B, the stack LS4, and the stack LS5 is similar to the corresponding configuration of the semiconductor device 1 according to the first embodiment.

An insulator 11B corresponding to the case CS is provided on an upper surface of the conductor 10. The insulator 11B includes, for example, PPC. A plurality of spaces penetrating from a lower end toward an upper end is formed in a part of the insulator 11B.

The conductor 17B-1 has a first end bonded on an upper surface of the conductor 15a-1 and a second end positioned on an upper surface of the insulator 11B and functioning as a terminal T.

The conductor 17B-2 has a first end bonded on an upper surface of the conductor 15a-2 and a second end positioned on an upper surface of the insulator 11B and functioning as the terminal T.

An internal structure of the semiconductor device 1B configured as described above is sealed by the insulator 20 except for the portion functioning as the terminal T in the conductors 17B-1 and 17B-2.

In addition, as illustrated in FIG. 7, a stack LS4 is provided in an internal space of the insulator 11B formed below the conductor 17B-1. The stack LS4 includes an insulator 21b and a conductor 22b. The insulator 21b is, for example, a flat insulating sheet, and includes a material different from the insulating substrate such as the insulator 14a. The conductor 22b contains, for example, copper (Cu).

An upper surface of the conductor 22b is in contact with a lower surface of the second end of the conductor 17B-1 functioning as the terminal T. A lower surface of the conductor 22b is in contact with an upper surface of the insulator 21b. A lower surface of the insulator 21b is in contact with an upper surface of the conductor 10. The insulator 21b electrically insulates the conductor 10 from the conductor 22b. As a result, the conductor 17B-1 functions as a path to transfer heat from the semiconductor element 16 to the conductor 10 through the conductor 22b and the insulator 21b, the heat would otherwise be transferred to the insulator or the terminal T if the conductor 17B-1 is not provided.

As illustrated in FIG. 8, a stack LS5 is provided in an internal space of an insulator 11B formed below a conductor 17B-2. The stack LS5 includes an insulator 21c and a conductor 22c. The conductor 22c is provided apart from the conductor 22b through the insulator 11B. Thus, the conductors 22b and 22c are electrically insulated. The insulator 21c is, for example, a flat insulating sheet, and includes a material different from the insulating substrate such as the insulator 14a. The conductor 22c contains, for example, copper (Cu).

An upper surface of the conductor 22c is in contact with a lower surface of the second end of the conductor 17B-2 functioning as the terminal T. A lower surface of the conductor 22c is in contact with an upper surface of the insulator 21c. A lower surface of the insulator 21c is in contact with an upper surface of the conductor 10. The insulator 21c electrically insulates the conductor 10 from the conductor 22c. As a result, the conductor 17B-2 functions as a path to transfer heat from the semiconductor element 16 to the conductor 10 through the conductor 22c and the insulator 21c, the heat would otherwise be transferred to the insulator 14a or the terminal T if the conductor 17B-2 is not provided.

Note that a first end of the conductor 17B-1 and the conductor 15a-1, a second end of the conductor 17B-1 and the conductor 22b, a first end of the conductor 17B-2 and the conductor 15a-2, and a second end of the conductor 17B-2 and the conductor 22c are bonded by ultrasonic bonding, for example. In this case, an indentation having fine protrusions and recesses as if a knurled shape is transferred is formed on each of the upper surfaces of the first end and the second end of the conductor 17B-1 and the first end and the second end of the conductor 17B-2.

According to the third embodiment, the insulator 21b and the conductor 22b, and the insulator 21c and the conductor 22c are provided in a space in the insulator 11B. The conductor 17B-1 has a first end in contact with the conductor 15a-1 and a second end in contact with the conductor 22b and located on the upper surface of the insulator 11B to function as the terminal T. The conductor 17B-2 has a first end in contact with the conductor 15a-2 and a second end in contact with the conductor 22c, located on the upper surface of the insulator 11B, and functioning as the terminal T. As a result, the conductors 17B-1 and 17B-2 can function as a heat radiation path for releasing the heat flowing into the terminal T and the stack LS1 to the conductor 10 through the conductors 22b and 22c, and can also function as a current path between the terminal T and the semiconductor element 16. In addition, since the heat radiation path can be formed in a space inside the insulator 11B, restrictions on the layout of the internal structure of the semiconductor device 1B can be alleviated as compared with the case where the heat radiation path is formed inside the insulator 11B.

### 4. Fourth Embodiment

Next, a semiconductor device according to a fourth embodiment will be described.

The fourth embodiment is different from the third embodiment in that a conductor provided inside a case CS and a bus bar electrically connecting a semiconductor element 16 and a terminal T are integrally formed. Hereinafter, a configuration different from that of the third embodiment will be mainly described. Description of configurations similar to those of the third embodiment will be omitted as appropriate.

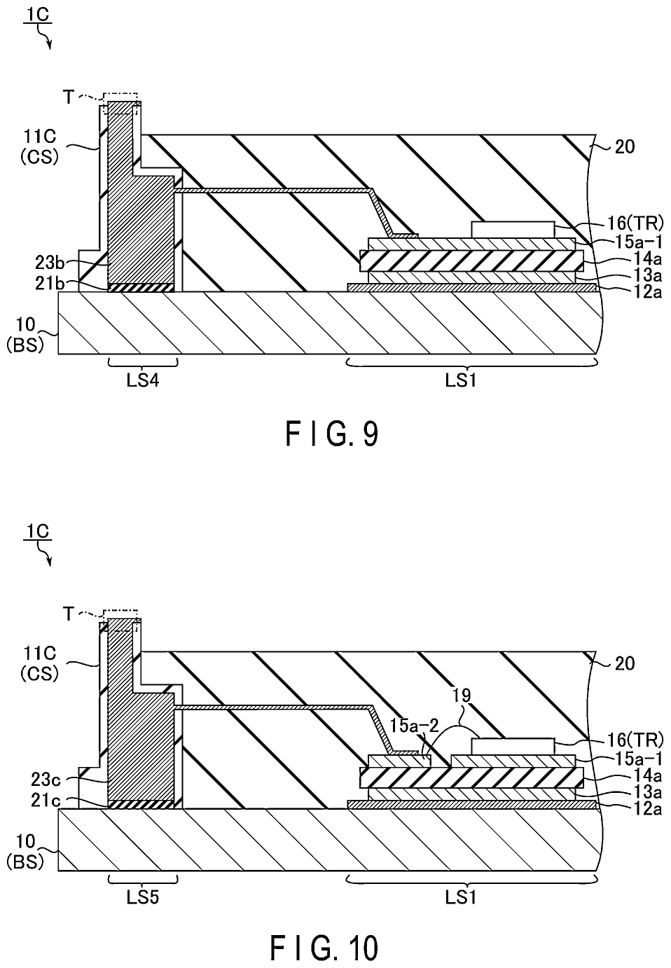

FIG. 9 is a cross-sectional view illustrating a first example of a cross-sectional structure of the semiconductor device according to the fourth embodiment. FIG. 10 is a cross-sectional view illustrating a second example of the cross-sectional structure of the semiconductor device according to the fourth embodiment. FIGS. 9 and 10 correspond to FIGS. 7 and 8 in the third embodiment, respectively.

A semiconductor device 1C according to the fourth embodiment includes an insulator 11C, a conductor 23b, and a conductor 23c in place of the insulator 11B, the conductors 17B-1 and 22b, and the conductors 17B-2 and 22c, respectively. The configuration of the semiconductor device 1C excluding the insulator 11C, the conductor 23b, and the conductor 23c is similar to the corresponding configuration of the semiconductor device 1B according to the third embodiment.

The insulator 11C corresponding to the case CS is provided on an upper surface of the conductor 10. The insulator 11C includes, for example, PPC. A plurality of spaces penetrating from the lower end toward the upper end is formed in a part of the insulator 11C. Each space is connected to the internal space of the semiconductor device 1C through a hole formed in the inner side surface of the insulator 11C.

As illustrated in FIG. 9, the conductor 23b includes a bus bar located in the internal space of the semiconductor device 1C, a heat radiation portion located inside the insulator 11C, and a terminal portion located on the upper surface of the insulator 11C. The bus bar of the conductor 23b has a first end bonded onto an upper surface of a conductor 15a-1 and a second end connected to the heat radiation portion of the conductor 23b through a hole formed in the inner side surface of the insulator 11C. The heat radiation portion of the conductor 23b has a lower surface in contact with the upper surface of the insulator 21b. The terminal portion of the conductor 23b is located above the heat radiation portion of the conductor 23b and functions as the terminal T. As a result, the conductor 23b functions as a path to transfer heat from the semiconductor element 16 to the conductor 10 through the insulator 21b, the heat would otherwise be transferred to the insulator 14a or the terminal T if the conductor 23b is not provided.

As illustrated in FIG. 10, the conductor 23c includes a bus bar located in the internal space of the semiconductor device 1C, a heat radiation portion located inside the insulator 11 C, and a terminal portion located on an upper surface of the insulator 11C. The bus bar of the conductor 23c has a first end bonded onto an upper surface of the conductor 15a-2 and a second end connected to the heat radiation portion of the conductor 23c through a hole formed in the inner side surface of the insulator 11C. The heat radiation portion of the conductor 23c has a lower surface in contact with the upper surface of the insulator 21c. The terminal portion of the conductor 23c is located above the heat radiation portion of the conductor 23c and functions as the terminal T. As a result, the conductor 23c functions as a path to transfer heat from the semiconductor element 16 to the conductor 10 through the insulator 21c, the heat would otherwise be transferred to the insulator 14a or the terminal T if the conductor 23c is not provided.

Note that a portion between the first end of the bus bar of the conductor 23b and the conductor 15a-1 and a portion between the first end of the bus bar of the conductor 23c and the conductor 15a-2 are bonded by, for example, ultrasonic bonding. In this case, an indentation having fine protrusions and recesses as if a knurled shape is transferred is formed on the upper surface of each of the first end of the bus bar of the conductor 23b and the first end of the bus bar of the conductor 23c.

According to the fourth embodiment, each of the conductors 23b and 23c includes a heat radiation portion, a bus bar, and a terminal portion. The heat radiation portion of the conductor 23b and the heat radiation portion of the conductor 23c are provided in a space in the insulator 11C. The bus bar of the conductor 23b has a first end in contact with the conductor 15a-1 and a second end connected to the heat radiation portion of the conductor 23b. The bus bar of the conductor 23c has a first end in contact with the conductor 15a-2 and a second end connected to the heat radiation portion of the conductor 23c. The terminal portion of the conductor 23b and the terminal portion of the conductor 23c are located on the upper surface of the insulator 11C and function as the terminal T. As a result, the conductors 23b and 23c can function as a heat radiation path for releasing the heat flowing into the terminal T and the stack LS1 to the conductor 10 through the insulators 21b and 21c, and can also function as a current path between the terminal T and the semiconductor element 16.

### 5. Fifth Embodiment

Next, a semiconductor device according to a fifth embodiment will be described.

The fifth embodiment is different from the fourth embodiment in that a stack including an insulating substrate is formed inside a case CS. Hereinafter, a configuration different from that of the fourth embodiment will be mainly described. Description of configurations similar to those of the fourth embodiment will be omitted as appropriate.

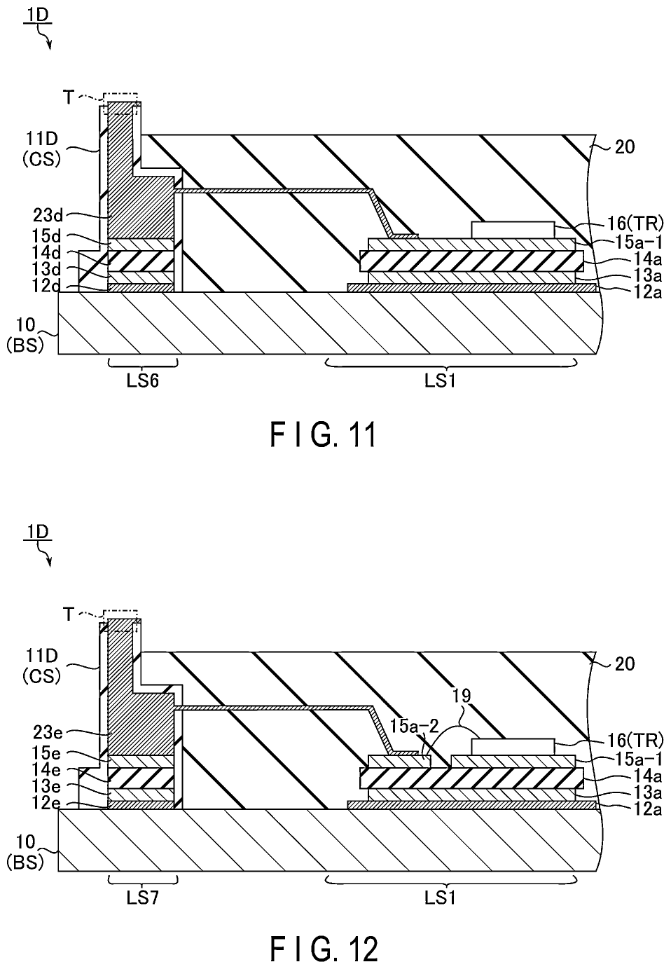

FIG. 11 is a cross-sectional view illustrating a first example of a cross-sectional structure of the semiconductor device according to the fifth embodiment. FIG. 12 is a cross-sectional view illustrating a second example of the cross-sectional structure of the semiconductor device according to the fifth embodiment. FIGS. 11 and 12 correspond to FIGS. 9 and 10 in the fourth embodiment, respectively.

The semiconductor device 1D according to the fifth embodiment includes an insulator 11D, a stack LS6, and a stack LS7 instead of the insulator 11C, the stack LS4, and the stack LS5, respectively. The configuration of the semiconductor device 1D excluding the insulator 11D, the stack LS6, and the stack LS7 is similar to the corresponding configuration of the semiconductor device 1C according to the fourth embodiment.

An insulator 11D corresponding to a case CS is provided on an upper surface of the conductor 10. The insulator 11D includes, for example, PPC. A plurality of spaces penetrating from the lower end toward the upper end is formed in a part of the insulator 11D. Each space is connected to an internal space of the semiconductor device 1D through a hole formed in the inner side surface of the insulator 11D.

As illustrated in FIG. 11, the stack LS6 includes a conductor 12d, a conductor 13d, an insulator 14d, a conductor 15d, and a conductor 23d. The conductor 12d is provided inside the insulator 11D on the upper surface of the conductor 10. The conductor 12d includes, for example, solder. The conductor 13d is provided on the upper surface of the conductor 12d. The conductor 13d contains, for example, copper (Cu). The insulator 14d is provided on an upper surface of the conductor 13d. The insulator 14d is, for example, an insulating substrate including insulating ceramics such as aluminum nitride (AlN) and silicon nitride (SiN). The conductor 15d is provided on an upper surface of the insulator 14d. The conductor 15d contains, for example, copper (Cu).

The conductor 23d includes a bus bar located in the internal space of the semiconductor device 1D, a heat radiation portion located inside the insulator 11D, and a terminal portion located on the upper surface of the insulator 11D. The bus bar of the conductor 23d has a first end bonded onto the upper surface of the conductor 15a-1 and a second end connected to the heat radiation portion of the conductor 23d through a hole formed in the inner side surface of the insulator 11D. The heat radiation portion of the conductor 23d has a lower surface in contact with the upper surface of the conductor 15d. The terminal portion of the conductor 23d is located above the heat radiation portion of the conductor 23d and functions as the terminal T. As a result, the conductor 23d functions as a path to transfer heat from the semiconductor element 16 to the conductor 10 through the stack LS4, the heat would otherwise be transferred to the insulator 14a or the terminal T if the conductor 23d is not provided.

As illustrated in FIG. 12, the stack LS7 includes a conductor 12e, a conductor 13e, an insulator 14e, a conductor 15e, and a conductor 23e. The conductor 12e is provided inside the insulator 11D on the upper surface of the conductor 10. The conductor 12e includes, for example, solder. The conductor 12e is provided on the upper surface of the conductor 13e. The conductor 13e contains, for example, copper (Cu). The insulator 14e is provided on an upper surface of the conductor 13e. The insulator 14e is, for example, an insulating substrate including insulating ceramics such as aluminum nitride (AlN) and silicon nitride (SiN). The conductor 15e is provided on the upper surface of the insulator 14e. The conductor 15e contains, for example, copper (Cu).

The conductor 23e includes a bus bar located in the internal space of the semiconductor device 1D, a heat radiation portion located inside the insulator 11D, and a terminal portion located on the upper surface of the insulator 11D. The bus bar of the conductor 23e has a first end bonded onto the upper surface of the conductor 15a-2 and a second end connected to the heat radiation portion of the conductor 23e through a hole formed in the inner side surface of the insulator 11D. The heat radiation portion of the conductor 23e has a lower surface in contact with the upper surface of the conductor 15e. The terminal portion of the conductor 23e is located above the heat radiation portion of the conductor 23e and functions as the terminal T. As a result, the conductor 23e functions as a path to transfer heat from the semiconductor element 16 to the conductor 10 through the stack LS5, the heat would otherwise be transferred to the insulator 14a or the terminal T if the conductor 23e is not provided.

According to the fifth embodiment, the conductor 12d includes solder, and the stack LS6 including the insulator 14d is bonded to the conductor 10 in the space in the insulator 11D. The conductor 12e includes solder, and bonds the stack LS7 including the insulator 14e to the conductor 10 inside the insulator 11D. As a result, a bonding strength between the stacks LS6 and LS7 and the conductor 10 can be improved.

Each of the conductors 23d and 23e includes a heat radiation portion, a bus bar, and a terminal portion. The heat radiation portion of the conductor 23d and the heat radiation portion of the conductor 23e are provided in a space in the insulator 11D. The bus bar of the conductor 23d has a first end in contact with the conductor 15a-1 and a second end connected to the heat radiation portion of the conductor 23d. The bus bar of the conductor 23e has a first end in contact with the conductor 15a-2 and a second end connected to the heat radiation portion of the conductor 23e. The terminal portion of the conductor 23d and the terminal portion of the conductor 23e are located on the upper surface of the insulator 11D and function as the terminal T. As a result, the conductors 23d and 23e can function as a heat radiation path for releasing the heat flowing into the terminal T and a stack LS1 to the conductor 10 through stacks LS6 and LS7, and can also function as a current path between the terminal T and the semiconductor element 16.

### 6. Modifications and the Like

Note that the first embodiment, the second embodiment, the third embodiment, the fourth embodiment, and the fifth embodiment are not limited to the above-described examples, and various modifications can be applied.

For example, in the first embodiment, the fourth embodiment, and the fifth embodiment described above, the case where the heat radiation path suppresses both the temperature rise of the stack LS1 and the terminal T has been described, but the present disclosure is not limited thereto. The heat radiation path for suppressing the temperature rise of the stack LS1 may be provided separately from the heat radiation path for suppressing the temperature rise of the terminal T.

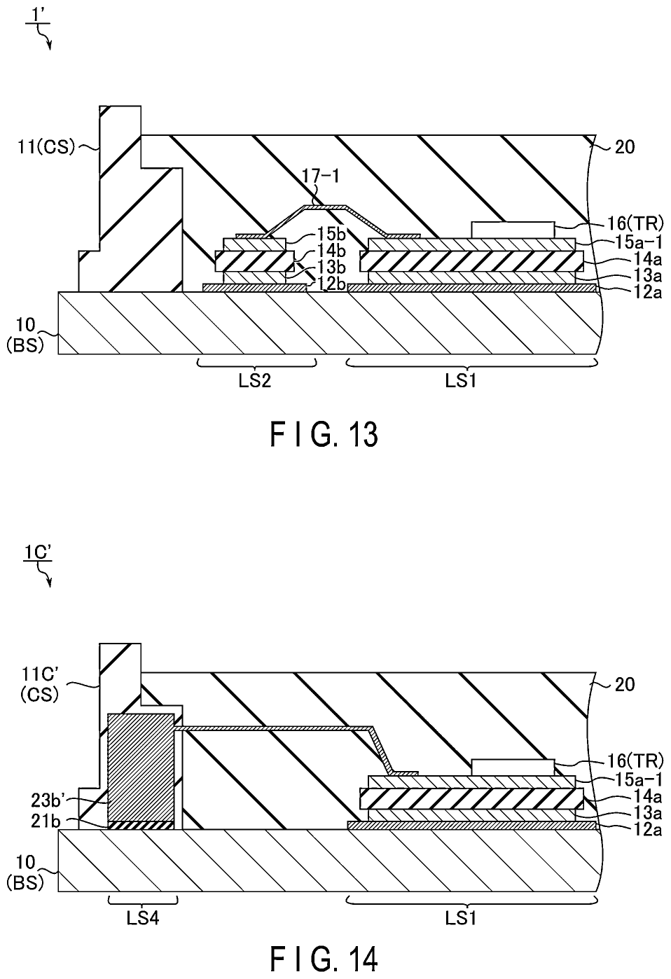

FIG. 13 is a cross-sectional view illustrating an example of a cross-sectional structure of a semiconductor device according to a first modification. FIG. 13 corresponds to FIG. 3 in the first embodiment.

As illustrated in FIG. 13, in a semiconductor device 1′ according to a first modification, a conductor 17-1 may be provided apart from a conductor 18-1. In this case, the conductor 17-1 and a stack LS2 connected to the conductor 17-1 mainly contribute to the suppression of the temperature rise of a stack LS1.

FIG. 14 is a cross-sectional view illustrating an example of a cross-sectional structure of a semiconductor device according to a second modification. FIG. 14 corresponds to FIG. 9 in the fourth embodiment.

As illustrated in FIG. 14, in a semiconductor device 1C′ according to the second modification, a conductor 23b′ has a bus bar and a heat radiation portion, but may not have a terminal portion. In this case, the conductor 23b′ and the insulator 21b connected to the conductor 23b′ mainly contribute to suppression of the temperature rise of the stack LS1.

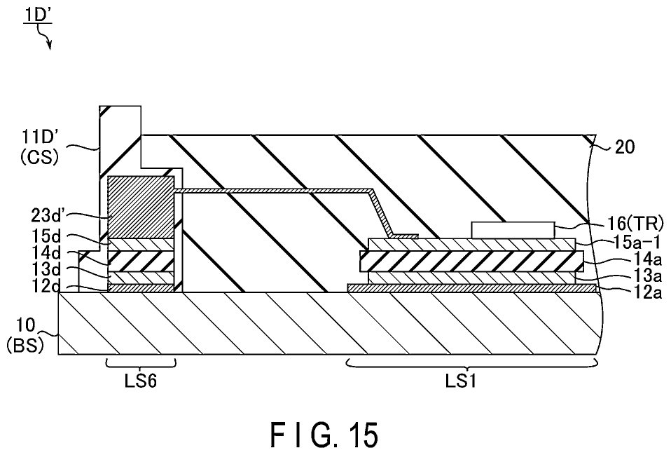

FIG. 15 is a cross-sectional view illustrating an example of a cross-sectional structure of a semiconductor device according to a third modification. FIG. 15 corresponds to FIG. 11 in the fifth embodiment.

As illustrated in FIG. 15, in a semiconductor device 1D′ according to the third modification, the conductor 23d′ has a bus bar and a heat radiation portion, but may not have a terminal portion. In this case, the conductor 23d′ and a stack LS6 connected to the conductor 23d′ mainly contribute to suppression of temperature rise of the stack LS1.

In the first embodiment, the second embodiment, the third embodiment, the fourth embodiment, and the fifth embodiment described above, the case where the bus bar is ultrasonically bonded has been described, but the present disclosure is not limited thereto. For example, the bus bars may be bonded using solder or a sintered material.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. A semiconductor device comprising:
a base substrate;
a case provided on an upper surface of the base substrate;
a first stack provided inside the case on the upper surface of the base substrate;
a second stack provided apart from the first stack on the upper surface of the base substrate; and
a first conductor having a flat plate shape and including a first portion in contact with the first stack and a second portion in contact with the second stack, wherein
the first stack includes a first insulator, a second conductor provided on an upper surface of the first insulator and in contact with the first portion of the first conductor, and a first semiconductor element electrically connected to the second conductor, and
the second stack includes a second insulator and a third conductor provided on an upper surface of the second insulator and in contact with the second portion of the first conductor, and does not include a semiconductor element.

2. The semiconductor device according to claim 1, wherein
the second stack is positioned between the first stack and the case.

3. The semiconductor device according to claim 2, further comprising
a fourth conductor having a third portion in contact with the first portion of the first conductor and a fourth portion located on an upper surface of the case and functioning as a terminal.

4. The semiconductor device according to claim 2, wherein
the first conductor further includes a fifth portion located on an upper surface of the case and functioning as a terminal.

5. The semiconductor device according to claim 1, wherein
the second stack is covered by the case.

6. The semiconductor device according to claim 5, wherein
the second portion of the first conductor is located on an upper surface of the case and functions as a terminal.

7. The semiconductor device according to claim 5, wherein
the second portion of the first conductor passes through an inner surface of the case and is in contact with the third conductor, and
the first conductor and the third conductor are one continuous member.

8. The semiconductor device according to claim 7, wherein
a material of the second insulator is different from a material of the first insulator.

9. The semiconductor device according to claim 7, wherein
a material of the second insulator is substantially equal to a material of the first insulator.

10. The semiconductor device according to claim 1, wherein
an internal space is formed in the case, the internal space penetrating from a lower end of the case toward an upper end of the case, and
the second stack is provided in the internal space.

11. The semiconductor device according to claim 10, wherein the second portion of the first conductor is located on an upper surface of the case and functions as a terminal.

12. The semiconductor device according to claim 10, wherein
the second portion of the first conductor passes through an inner surface of the case and is in contact with the third conductor, and
the first conductor and the third conductor are one continuous member.

13. The semiconductor device according to claim 12, wherein
a material of the second insulator is different from a material of the first insulator.

14. The semiconductor device according to claim 12, wherein
a material of the second insulator is substantially equal to a material of the first insulator.

15. The semiconductor device according to claim 3, wherein
a width of the first conductor is longer than a width of the fourth conductor.

16. The semiconductor device according to claim 15, wherein
the first conductor has a portion that is not hidden by the fourth conductor when viewed from above to below.
